(19) United States
(12) Patent Application Publication
(10) Pub. No.: US 2025/0234586 A1
(43) Pub. Date: Jul. 17, 2025

(54) SYSTEM AND METHOD FOR ESTIMATING JUNCTION TEMPERATURE OF SEMICONDUCTOR POWER MODULE

(71) Applicant: Ford Global Technologies, LLC, Dearborn, MI (US)

(72) Inventors: Jogendra Singh Thongam, Windsor (CA); Baoming Ge, Okemos, MI (US); Fan Wang, Novi, MI (US); Lee Caldwell, Plymouth, MI (US); Molly Mazzella, Brownstown, MI (US); Craig Rogers, Belleville, MI (US); Kevin Newman, Farmington Hills, MI (US); Milind B. Kulkarni, Livonia, MI (US)

(21) Appl. No.: 18/410,645

(22) Filed: Jan. 11, 2024

(51) Int. Cl. H01L 29/78; B60L 3/00; H01L 27/092; H01L 29/16

(52) U.S. Cl. CPC H10D 30/659; B60L 3/003; H10D 62/8325; H10D 84/85; B60L 2240/525

(57) ABSTRACT

Systems and methods for estimating the junction temperature of a semiconductor power device or a power module are described. The power module may include one or more SiC metal oxide semiconductor field effect transistors and the temperature is a junction temperature of the one or more SiC metal oxide semiconductor field effect transistors. The temperature of the power module may be a basis for adjusting operation of a vehicle.

### FIELD

The present description relates to methods and a system for estimating a junction temperature of a semiconductor power module. In one example, the semiconductor power module includes N-channel or P-channel silicon carbide (SiC) metal oxide semiconductor field effect transistors (MOSFETs).

### BACKGROUND AND SUMMARY

A vehicle may include semiconductor power modules to control flow of power through electric devices. For example, an electric or hybrid vehicle may include an inverter that may convert direct current (DC) output of a traction battery to alternating current (AC) that powers a traction motor. The inverter may include a power module that may include one or more MOSFETS. The inverter may be exposed to a range of ambient temperatures, electric loads, and other operating conditions that may affect operation of the power module. Therefore, it may be desirable to provide an accurate estimate of a junction temperature for the power devices.

### BRIEF DESCRIPTION OF THE DRAWINGS

The advantages described herein will be more fully understood by reading an example of an embodiment, referred to herein as the Detailed Description, when taken alone or with reference to the drawings, where:

FIG. 1 is a schematic view of an example electric vehicle;

FIG. 2 is a schematic diagram of an example inverter.

FIG. 3 is a block diagram of a method for estimating a junction temperature of a power module;

FIG. 4 is a schematic diagram that illustrates positioning of a temperature sensor;

FIG. 5 is a plot of an example function that describes a temperature difference between a junction temperature of a power device and a temperature of a direct bonded copper (DBC) substrate;

FIGS. 6-8 are plots of temperatures for a power device;

FIG. 9 is an example method for estimating at junction temperature for a power device; and

FIG. 10 is a schematic diagram of an example SiC MOSFET.

### DETAILED DESCRIPTION

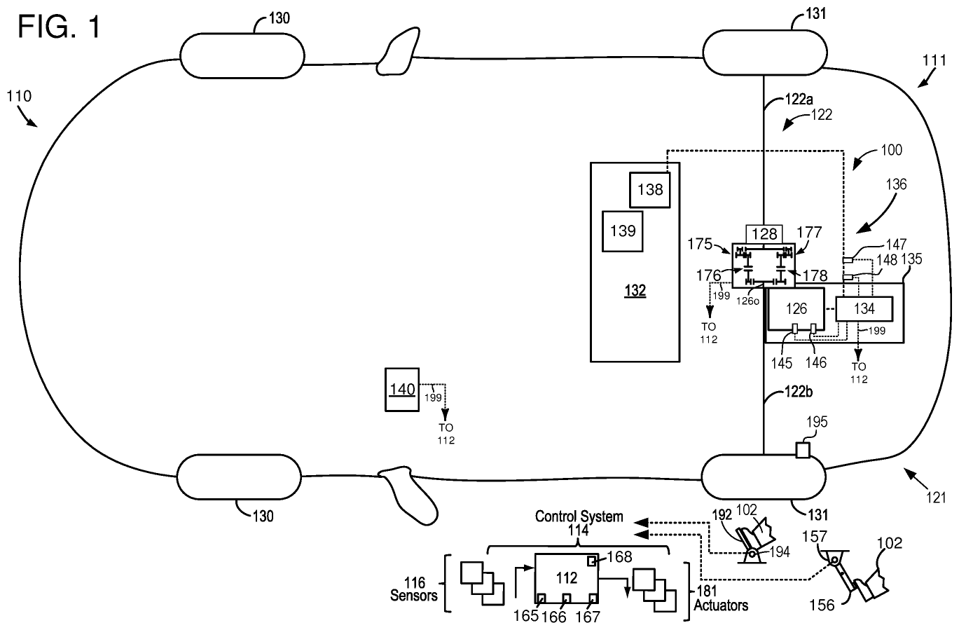

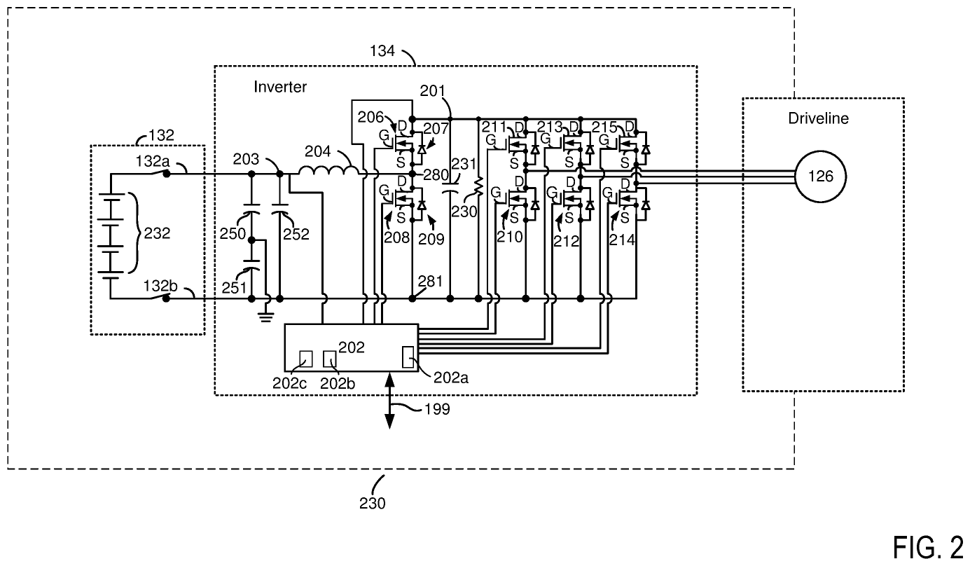

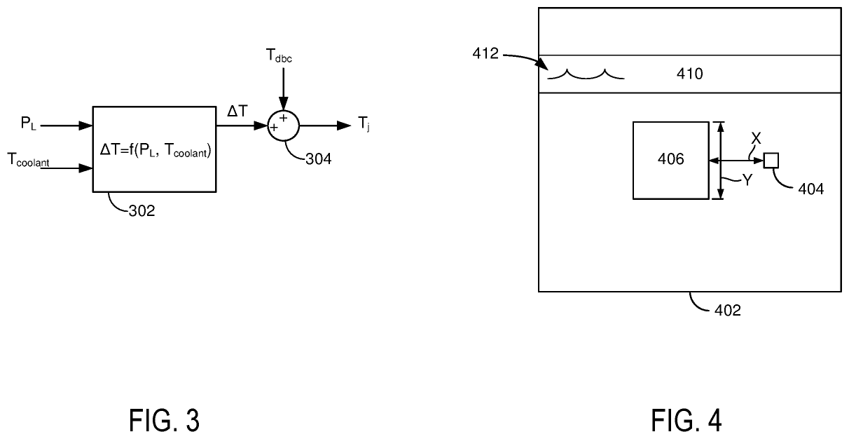

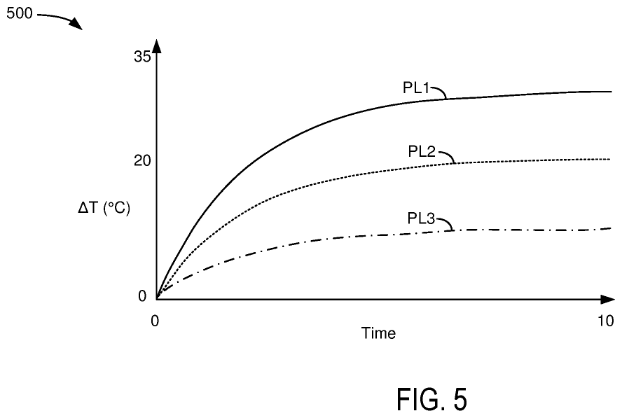

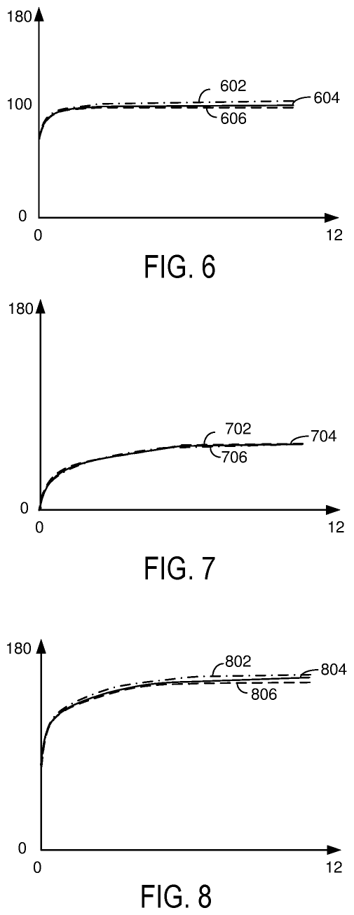

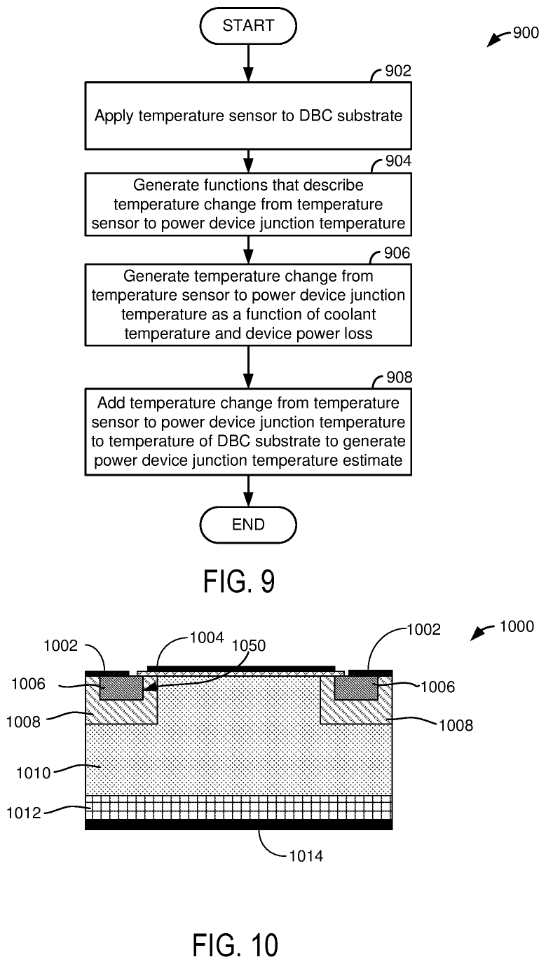

The present description is related to estimating a junction temperature of a semiconductor power device. The power device may be incorporated into a vehicle of the type that is shown in FIG. 1. The power device may be included in an inverter for an electric traction machine as shown in FIG. 2. The junction temperature of the power device may be estimated as shown in the block diagram of FIG. 3. The power device and a temperature sensor may be embedded to a direct bonded copper substrate as shown in FIG. 4. An example relationship between a temperature difference between the junction and DBC for various power losses of the power device is shown in FIG. 5. Additional temperature relationships are shown in FIGS. 6-8. An example method for determining a junction temperature of a power device is shown in FIG. 9. A conceptual view of an example silicon carbide (SiC) MOSFET is shown in FIG. 10.

SiC MOSFETs may be a desirable replacement for insulated gate bipolar transistors (IGBTs) because they offer lower losses, higher switching speeds, higher voltage capacities, and higher junction temperature constraining thresholds. However, IGBTs may be preferred in some cases because they may include an integrated temperature sensor for determining a junction temperature within the IGBT. Knowing the junction temperature is useful information for protecting the IGBT from over temperature conditions. On the other hand, SiC MOSFETs presently do not include integral junction temperature sensors due to financial expense and complexity. Junction temperatures of SiC MOSFETs may be estimated based on a flow rate of coolant that is supplied to cool the SiC MOSFETs. However, adding a coolant flow sensor to a system and estimating junction temperature based on output of a flow sensor may increase system financial expense and increase system complexity.

The inventors herein have recognized the above-mentioned issues and have developed a method for estimating the junction temperature of a power device, comprising: via a controller, estimating a temperature difference between a junction temperature of a power device and a temperature of a substrate; and via the controller, estimating the temperature of the power device via adding the temperature of the substrate and the temperature difference between the junction temperature of the power device and the temperature of the substrate.

By inferring a junction temperature of a power device based on a temperature of a substrate and a temperature difference between the junction of the power device and the substrate, it may be possible to provide the technical result of lowering system financial expense and generating an accurate junction temperature estimate for the power device. In one example, the temperature difference between the junction of the power device and the substrate may be a function of losses of the power device and the temperature of coolant supplied to cool the power device.

The present description may provide several advantages. In particular, the approach may reduce financial expense of determining a junction temperature of a power device. Further, the approach may provide an accurate estimate of the junction temperature of the power device. Additionally, the approach includes ways to reduce a possibility of degradation of the power device.

The above advantages and other advantages, and features of the present description will be readily apparent from the following Detailed Description when taken alone or in connection with the accompanying drawings.

It may be understood that the summary above is provided to introduce in simplified form a selection of concepts that are further described in the detailed description. It is not meant to identify key features of the claimed subject matter, the scope of which is defined uniquely by the claims that follow the detailed description. Furthermore, the claimed subject matter is not limited to implementations that solve any disadvantages noted above or in any part of this disclosure.

FIG. 1 is a block diagram of a vehicle 121 including a powertrain or driveline 100. A front portion of vehicle 121 is indicated at 110 and a rear portion of vehicle 121 is indicated at 111. Driveline 100 includes electric machine 126. Electric machine 126 may consume or generate electrical power depending on its operating mode. Throughout the description of FIG. 1, mechanical connections between various components are illustrated as solid lines, whereas electrical connections between various components are illustrated as dashed lines.

Driveline 100 has a rear axle 122. In some examples, rear axle 122 may comprise two half shafts, for example first half shaft 122a, and second half shaft 122b. Driveline 100 also includes front wheels 130 and rear wheels 131. Rear wheels 131 may be driven via electric machine 126.

The rear axle 122 is coupled to electric machine 126. Rear drive unit 136 may transfer power from electric machine 126 to axle 122 resulting in rotation of rear wheels 131. Rear drive unit 136 may include a low gear 175 and a high gear 177 that are coupled to electric machine 126 via output shaft 1260 of electric machine 126. Low gear 175 may be engaged via fully closing low gear clutch 176. High gear 177 may be engaged via fully closing high gear clutch 178. High gear clutch 178 and low gear clutch 176 may be opened and closed via commands received by rear drive unit 136 over controller area network (CAN) 199. Alternatively, high gear clutch 178 and low gear clutch 176 may be opened and closed via digital outputs or pulse widths provided via control system 114. Rear drive unit 136 may include differential 128 so that torque may be provided to first half shaft 122a and to second half shaft 122b. In some examples, an electrically controlled differential clutch (not shown) may be included in rear drive unit 136.

Electric machine 126 may receive electrical power from onboard electric energy storage device 132. Furthermore, electric machine 126 may provide a generator function to convert the vehicle's kinetic energy into electrical energy, where the electrical energy may be stored at electric energy storage device 132 for later use by electric machine 126. A power converter/inverter 134 may convert alternating current generated by electric machine 126 to direct current for storage at the electric energy storage device 132 and vice versa. Electric drive system 135 includes electric machine 126 and power converter 134. Electric energy storage device 132 may be a traction battery (e.g., a battery that supplies power to propel a vehicle), capacitor, inductor, or other electric energy storage device. Electric power flowing into electric drive system 135 may be monitored via current sensor 145 and voltage sensor 146. Position and speed of electric machine 126 may be monitored via position sensor 147. Torque generated by electric machine 126 may be monitored via torque sensor 148.

In some examples, electric energy storage device 132 may be configured to store electrical energy that may be supplied to other electrical loads residing on-board the vehicle (other than the motor), including cabin heating and air conditioning, engine starting, headlights, cabin audio and video systems, etc.

Control system 114 may communicate with electric machine 126, electric energy storage device 132, etc. Control system 114 may receive sensory feedback information from electric drive system 135 and electric energy storage device 132, etc. Further, control system 114 may send control signals to electric drive system 135 and electric energy storage device 132, etc., responsive to this sensory feedback. Control system 114 may receive an indication of an operator requested output of the vehicle propulsion system from a human operator 102, or an autonomous controller. For example, control system 114 may receive sensory feedback from pedal position sensor 194 which communicates with pedal 192. Pedal 192 may refer schematically to a driver demand pedal. Similarly, control system 114 may receive an indication of an operator requested vehicle slowing via a human operator 102, or an autonomous controller. For example, control system 114 may receive sensory feedback from pedal position sensor 157 which communicates with vehicle wheel caliper activating pedal 156.

Electric energy storage device 132 may periodically receive electrical energy from a power source such as a stationary power grid (not shown) residing external to the vehicle (e.g., not part of the vehicle). As a non-limiting example, driveline 100 may be configured as a plug-in electric vehicle (EV), whereby electrical energy may be supplied to electric energy storage device 132 via the power grid (not shown).

Electric energy storage device 132 includes an electric energy storage device controller 139 and a power distribution module 138. Electric energy storage device controller 139 may provide charge balancing between energy storage element (e.g., battery cells) and communication with other vehicle controllers (e.g., controller 112). Power distribution module 138 controls flow of power into and out of electric energy storage device 132.

One or more wheel speed sensors (WSS) 195 may be coupled to one or more wheels of driveline 100. The wheel speed sensors may detect rotational speed of each wheel. Such an example of a WSS may include a permanent magnet type of sensor.

Controller 112 may comprise a portion of a control system 114. In some examples, controller 112 may be a single controller of the vehicle. Control system 114 is shown receiving information from a plurality of sensors 116 (various examples of which are described herein) and sending control signals to a plurality of actuators 181 (various examples of which are described herein). As one example, sensors 116 may include tire pressure sensor(s) (not shown), wheel speed sensor(s) 195, etc. In some examples, sensors associated with electric machine 126, wheel speed sensor 195, etc., may communicate information to controller 112, regarding various states of electric machine operation. Controller 112 includes non-transitory (e.g., read exclusive memory) 165, random access memory 166, digital inputs/outputs 168, and a microcontroller 167. Controller 112 may receive input data and provide data to human/machine interface 140 via CAN 199.

Referring now to FIG. 2, power converter 134 is shown electrically coupled to electric energy storage device 132 (e.g., battery). In this example, electric energy storage device includes a plurality of battery cells 232 that are connected in series to increase a voltage of electric energy storage device 132. Power converter 134 is also shown being electrically coupled to electric machine 126 (e.g., a three phase electric machine that may be operated as a motor or a generator). Inverter 134 includes a controller 202 that may communicate with controller 112 shown in FIG. 1 via controller area network (CAN) 199. Controller 202 is electrically coupled to gates (G) of transistors 206, 208, and 210-215. Controller 202 may supply control signals to independently activate and deactivate transistors 206, 208, and 210-215. Controller 202 includes inputs and outputs 202a (e.g., digital inputs, digital outputs, analog inputs, analog outputs), memory 202b (e.g., read exclusive memory, electrically erasable memory, transitory memory RAM), and processor 202c. Controller 202 may sense voltage at node 203 and current flow through inductor 204 via current sensor 299.

Transistors 206, 208, and 210-215 are shown as metal oxide silicon field effect transistors (MOSFETs), specifically SiC MOSFETs. Controller 202 may activate MOSFETs via supplying a higher potential voltage to gates of transistors 206, 208, and 210-215. Controller 202 may deactivate MOSFETs via supplying a lower potential voltage to gates of transistors 206, 208, and 210-215. Gates of transistors 206 and 208 are indicted by the letters “G.” Drains of transistors 206 and 208 are indicated by letters “D.” Sources of transistors 206 and 208 are indicated by letters “S.” Transistors 210-215 have similar gates, drains, and sources as indicated for transistors 206 and 208. Transistors 206 and 208 also include diodes 207 and 209, which are forward biased between the respective drains and sources. Current may flow between the drains and the sources of transistors 206 and 208 when they are activated. Current flow between the drains and sources of transistors 206 and 208 is prevented when transistors 206 and 208 are deactivated. Transistors 210-215 operate similarly. Transistors 210-215 may be selectively activated and deactivated to convert DC to AC.

Inductor 204 is shown directly electrically coupled to transistors 206 and 208. Inductor 204 is also directly electrically coupled to capacitor 250, capacitor 252, and electric energy storage device 132. Capacitor 251 is shown electrically coupled to capacitor 250 and a negative side of electric energy storage device 132.

In a boost mode, controller 202 may selectively activate transistor 208, which may be referred to as a boost transistor, to charge inductor 204 via charge provided by electric energy storage device 132 from positive terminal 133a. Inductor 204 impedes current flow as it begins to store electric energy in a magnetic field. The polarity of the left hand side of inductor 204 is positive when boost transistor 208 is closed. Current flow through inductor 204 is reduced and its magnetic field begins to become weakened when boost transistor 208 is opened. The polarity of inductor 204 changes so that the right side of inductor 204 has the positive polarity as its retracting magnetic field supports continuing current flow to the load. The voltage of electric energy storage device 132 and the voltage developed across inductor 204 are connected in series, thereby providing the voltage of electric energy storage device 132 plus the voltage of inductor 204 at node 280. The voltage at node 280 less a small voltage drop across diode 207 develops at node 201, which is the output of the variable voltage control inverter boost circuit and input to transistors 210-215 when VVC is operating in a boost mode, since diode 207 is forward biased. Charge may be stored in capacitor 231 to smooth the output voltage of the boost circuit at node 201. The voltage at node 201 is a DC voltage. The variable voltage control inverter boost circuit may include capacitors 250-252, inductor 204, boost transistor 208, diode 209, diode 207, capacitor 231, and resistor 230. The voltage at node 201 is supplied to transistors 210-215 which switch on and off to provide three phase AC power to electric machine 126. Buck transistor 206 is off whenever boost transistor 208 is on so as to prevent short circuiting between node 201 and node 281.

If a small amount of power is requested of electric machine 126, battery voltage minus small voltage drops for inductor 204 and diode 207 may be supplied at node 201 by deactivating buck transistor 206 and boost transistor 208.

In a buck mode, charge is supplied to inductor 204 via electric machine 126. In particular, three phase AC output of electric machine is converted into a DC voltage at node 201 via switching of transistors 210-215 by controller 202. Inductor 204 is charged via activating transistor 206, which may be referred to as a buck transistor. Inductor 204 impedes current flow as it begins to store electric energy in a magnetic field. The polarity of the right hand side of inductor 204 is positive when boost transistor 206 is closed. Current flow through inductor 204 is reduced and its magnetic field begins to become weakened when buck transistor 206 is opened. The polarity of inductor 204 changes so that the left side of inductor 204 has the positive polarity as its constricting magnetic field supports continuing current flow to the load (e.g., electric energy storage device 132). The amount of time inductor 204 is allowed to charge is controlled so that voltage that develops across inductor 204 is less than voltage output via the electric machine 126. Diode 209 couples the right side of inductor 204 to node 281, which is coupled to negative battery terminal 133b. The voltage developed across inductor 204 is connected to positive terminal 133a of electric energy storage device 132. Charge from inductor 204 flows to terminal 133a so that the electric energy storage device may charge. The voltage at node 203 is controlled via adjusting the amount of time buck transistor 206 is activated (e.g., closed to allow current flow through the transistor). Boost transistor 208 is deactivated (e.g., opened to inhibit current flow through the transistor) whenever buck transistor 206 is activated. Charge may be stored in capacitors 250-252 to smooth the output voltage of the buck circuit at node 203. The voltage at node 203 is a DC voltage. The variable voltage control inverter buck circuit may include capacitors 250-252, inductor 204, buck transistor 206, diode 209, capacitor 231, and resistor 230. Voltage and node 203 is the output voltage of the variable voltage control inverter buck circuit. Controller 202 may monitor voltages at nodes 203 and 201. Further, controller 202 may adjust the duty cycle of signals supplied to boost transistor 208 and buck transistor 206 responsive to voltages at nodes 203 and 201.

Referring now to FIG. 3, a block diagram of a method to determine a junction temperature for a power device (e.g., a power transistor) is shown. Block 302 represents a temperature difference (e.g., ΔT) being determined for a temperature difference between a power device junction temperature and a substrate temperature. The temperature difference may be mapped from empirical or model data and stored as a function of power losses P_{L} of the power device and a coolant temperature (e.g., a temperature of coolant that is supplied to cool the power device and the substrate). The power losses may be determined via a data sheet for the device and the coolant temperature may be determined via a temperature sensor as shown in FIG. 4. The output of block 302 is a temperature difference (ΔT) and the temperature difference is input to summing junction 304 where it is added to a temperature of the direct bonded copper substrate (T_{dbc}). The sum of the temperature difference and the temperature of the substrate is equal to the junction temperature Tⱼ of the power device.

Referring now to FIG. 4, a schematic diagram that illustrates positioning of a temperature sensor for estimating junction temperature of a power device is shown. Power semiconductor device 406 (e.g., a MOSFET or power module that may include a plurality of MOSFETs) is shown coupled to substrate 402. In one example, substrate 402 is a direct bonded copper substrate. Temperature sensor 404 is also coupled to substrate 402. Temperature sensor 404 is shown a distance X away from power device 406 and it may be desirable to minimize the distance X to provide a more accurate estimate of a junction temperature of power device 406. Notably, temperature sensor 404 is also positioned to the center of dimension Y to increase accuracy of the junction temperature estimate and power device 406 does not include an integral temperature sensor. Coolant 412 may be supplied via cooling passage or conduit 410 to cool substrate 402.

The system of FIGS. 1-4 provides for a system for estimating a temperature of a power device, the system comprising: a direct bonded copper (DBC) substrate, the power device embedded to the DBC substrate; a temperature sensor; and a controller including executable instructions stored in controller memory that cause the controller to estimate a junction temperature of the power device in response to an estimated temperature difference between the junction temperature and a DBC substrate temperature. In a first example, the system includes where the temperature sensor is mounted on the DBC. In a second example that may include the first example, the system further comprises additional instructions to determine the temperature of the DBC substrate from output of the temperature sensor. In a third example that may include one or both of the first and second examples, the system further comprises additional instructions to determine the junction temperature based on a temperature of a coolant and power loss of the power device. In a fourth example that may include one or more of the first through third examples, the system includes where the power device is a SiC metal oxide silicon field effect transistor (MOSFET). In a fifth example that may include one or more of the first through fourth examples, the system includes where the junction temperature is a temperature within the power device. In a sixth example that includes one or more of the first through fifth examples, the system further comprises additional instructions to adjust operation of the power device in response to the junction temperature.

Referring now to FIG. 5, a plot of an example relationship between coolant temperature, power device power loss, and a temperature difference between a power device junction temperature and a substrate temperature is shown. Plot 500 represents a relationship between the temperature difference between a power device junction temperature and a substrate temperature for a single or sole coolant temperature. A plurality or relationships may be provided for different coolant temperatures so that relationships between coolant temperature, power device power loss, and a temperature difference between a power device junction temperature and a substrate temperature may be known for a wide variety of operating conditions. Curves PL1, PL2, and PL3 represent the temperature difference between power device junction temperature and substrate temperature for different power loss levels for a sole coolant temperature. The vertical axis represents the temperature difference between the power device junction and the substrate. The horizontal axis represents time and time increases from the left side of the plot to the right side of the plot.

Referring now to FIG. 6, a plot of substrate temperature for different coolant flow rates is shown. The vertical axis represents substrate temperature. The horizontal axis represents time. Dash-dot trace 602 represents the temperature of the substrate for a lower coolant flow rate. Solid line trace 604 represents the temperature of the substrate for a middle coolant flow rate. Dashed trace 606 represents the temperature of the substrate for a higher coolant flow rate.

Referring now to FIG. 7, a plot of differences between the power device junction temperature and substrate temperature for different coolant flow rates is shown. The vertical axis represents the difference between the power device junction temperature and the substrate temperature. The horizontal axis represents time. Dash-dot trace 702 represents the temperature difference between the power device junction temperature and the substrate temperature for a lower coolant flow rate. Solid line trace 704 represents the temperature difference between the power device junction temperature and the substrate temperature for a middle coolant flow rate. Dashed trace 706 represents the temperature difference between the power device junction temperature and the substrate temperature for a higher coolant flow rate.

Referring now to FIG. 8, a plot of junction temperatures for different coolant flow rates is shown. The vertical axis represents power device junction temperature. The horizontal axis represents time. Dash-dot trace 802 represents the power device junction temperature for a lower coolant flow rate. Solid line trace 804 represents the power device junction temperature for a middle coolant flow rate. Dashed trace 806 represents the power device junction temperature for a higher coolant flow rate.

Referring now to FIG. 9, a method for estimating a junction temperature for a power device is shown. At least portions of method 900 may be included as executable instructions stored in non-transitory memory of a controller. Further, some portions of method 900 may be actions performed in the physical world via the controller and one or more actuators. Additionally, at least portions of method 900 may be performed via a human and/or a server computer.

At 902, method 900 applies a temperature sensor to a substrate that is a part of power module that includes power devices. The temperature sensor may be mounted on the substrate. Method 900 proceeds to 904.

At 904, method 900 generates a function or relationship that describes a temperature change between a temperature of a substrate and a junction temperature of a-power device. The temperature change values may be empirically determined via operating the power device at different power loss levels while adjusting the coolant flow rate and measuring or modeling the junction temperature and substrate temperature. The function or relationship may be described via relationships between system inputs and outputs. The functions are stored in controller memory. Method 900 proceeds to 906.

At 906, method 900 generates a temperature change value that is based on power loss of the power device and coolant temperature. The temperature change value may be determined via referencing the function or relationship determined at 904 and referencing the function or relationship via power device power loss and coolant temperature. The temperature change value is a temperature difference between a power device junction temperature and substrate temperature. Method 900 proceeds to 908 after the temperature change between the substrate and the junction temperature is determined.

At 908, method 900 adds the temperature change from step 906 to the temperature of the substrate to generate the power device junction temperature. The temperature of the substrate may be a direct bonded copper substrate temperature.

In some examples, method 900 may also compare the junction temperature against a threshold temperature. If the junction temperature is within a threshold temperature of the power device junction, method 900 may reduce power flow through the power device and/or other electric devices. For example, if the power device is transistor 210 in FIG. 2, method 900 may command inverter 134 to a lower power output level, thereby reducing electric current flow through transistor 210. At the same time, power flow through transistors 212 and 214 may be reduced. In this way, operation of the power device and its associated electric devices may be adjusted to reduce a possibility of system degradation.

Thus, method 900 may determine a junction temperature of a power device and reduce power output of the power converter and/or other electric devices to reduce a possibility of system degradation. For power modules for which a single junction temperature is estimated, operation of other power devices may be adjusted.

The method of FIG. 9 provides for a method for estimating a power device junction temperature, comprising: via a controller, estimating a temperature difference between the power device junction temperature and a temperature of a substrate; and via the controller, estimating the power device junction temperature via adding the temperature of the substrate and the temperature difference between the power device junction and the substrate. In a first example, the method further comprises adjusting operation of the power device in response to the temperature of the power device. In a second example that may include the first example, the method includes where adjusting operation of the power device includes reducing an amount of power flowing through the power device. In a third example that may include one or both of the first and second examples, the method includes where the temperature difference is based on a power loss amount of the power device. In a fourth example that may include one or more of the first through third examples, the method includes where the temperature difference is also based on a temperature of a coolant. In a fifth example that may include one or more of the first through fourth examples, the method includes where the power device is a SiC metal oxide semiconductor field effect transistor (MOSFET). In a sixth example that may include one or more of the first through fifth examples, the method includes, where the power device is an n-channel MOSFET. In a seventh example that may include one or more of the first through sixth examples, the method includes where the power device is a p-channel MOSFET.

The method of FIG. 9 also provides for a method for estimating a junction temperature of a power device, comprising: generating one or more relationships between a temperature difference between the junction temperature of the power device and the temperature of a substrate; storing the one or more relationships to memory of a controller; via the controller, estimating the temperature difference based on the one or more relationships; and via the controller, estimating the temperature of the power device via adding the temperature of the substrate and the temperature difference between the junction temperature of the power device and the temperature of the substrate. In a first example, the method further comprises adjusting operation of a second power device in response to the temperature of the power device. In a second example that may include the first example, the method includes where the power device is a SiC metal oxide semiconductor field effect transistor (MOSFET). In a third example that may include one or both of the first and second examples, the method includes where the second power device is a second SiC (MOSFET). In fourth example that may include one or more of the first through third examples, the method includes where the power device is part of an inverter.

Referring now to FIG. 10, a schematic illustrative view of an example SiC MOSFET is shown. MOSFET 1000 includes a gate 1004, drain 1014, and source 1002. A gate oxide layer 1005 is shown positioned between gate 1004 and n-drift layer 1010. MOSFET 1000 also includes N+ regions 1006, p doped well 1008, n-drift layer 1010, and n+ substrate 1012. The junction temperature mentioned herein is a temperature that is internal to MOSFET 1000. The junction temperature may be a temperature between the junction 1050 that lies between the p doped well 1008 and the N+ region.

The methods and routines disclosed herein may be stored as executable instructions in non-transitory memory and may be carried out by a system including the controller in combination with the various sensors and actuators. Further, portions of the methods may be physical actions taken in the real world to change a state of a device. The specific routines described herein may represent one or more of any number of processing strategies such as event-driven, interrupt-driven, multi-tasking, multi-threading, and the like. As such, various actions, operations, and/or functions illustrated may be performed in the sequence illustrated, in parallel, or in some cases omitted. Likewise, the order of processing is not necessarily required to achieve the features and advantages of the examples described herein, but is provided for ease of illustration and description. One or more of the illustrated actions, operations and/or functions may be repeatedly performed depending on the particular strategy being used. Further, the described actions, operations and/or functions may graphically represent code to be programmed into non-transitory memory of the computer readable storage medium in the system, where the described actions are carried out by executing the instructions in a system including the various hardware components in combination with the electronic controller. One or more of the method steps described herein may be omitted if desired.

While various embodiments have been described above, it may be understood that they have been presented by way of example, and not limitation nor restriction. It will be appreciated that the configurations and routines disclosed herein are exemplary in nature, and that these specific examples are not to be considered in a limiting sense, because numerous variations are possible. For example, the above technology can be applied to powertrains that include different types of propulsion sources including different types of electric machines, internal combustion engines, and/or transmissions. The technology may be used as a stand-alone, or used in combination with other power transmission systems not limited to machinery and propulsion systems for tandem axles, electric tag axles, P4 axles, HEVs, BEVs, agriculture, marine, motorcycle, recreational vehicles and on and off highway vehicles, as an example. The subject matter of the present disclosure includes all novel and non-obvious combinations and sub-combinations of the various systems and configurations, and other features, functions, and/or properties disclosed herein. It will be apparent to persons skilled in the relevant arts that the disclosed subject matter may be embodied in other specific forms without departing from the spirit of the subject matter.

The following claims particularly point out certain combinations and sub-combinations regarded as novel and non-obvious. These claims may refer to “an” element or “a first” element or the equivalent thereof. Such claims may be understood to include incorporation of one or more such elements, neither requiring nor excluding two or more such elements. Other combinations and sub-combinations of the disclosed features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure. As used herein, the term “approximately” is construed to mean plus or minus five percent of the range, unless otherwise specified.

1. A method for estimating a power device junction temperature, comprising:
via a controller, estimating a temperature difference between the power device junction temperature and a temperature of a substrate; and
via the controller, estimating the power device junction temperature via adding the temperature of the substrate and the temperature difference between the power device junction and the substrate.

2. The method of claim 1, further comprising adjusting operation of a power device in response to the power device junction temperature.

3. The method of claim 2, where adjusting operation of the power device includes reducing an amount of power flowing through the power device.

4. The method of claim 1, where the temperature difference is based on a power loss amount of the power device.

5. The method of claim 4, where the temperature difference is also based on a coolant temperature.

6. The method of claim 1, where the electric device is a SiC metal oxide semiconductor field effect transistor (MOSFET).

7. The method of claim 6, where the power device is an n-channel MOSFET.

8. The method of claim 6, where the power device is a p-channel MOSFET.

9. A system for estimating a temperature of a power device, the system comprising:
a direct bonded copper (DBC) substrate, the power device embedded to the DBC substrate;
a temperature sensor; and
a controller including executable instructions stored in controller memory that cause the controller to estimate a junction temperature of the power device in response to an estimated temperature difference between the junction temperature and a DBC substrate temperature.

10. The system of claim 9, where the temperature sensor is mounted on the DBC.

11. The system of claim 9, further comprising additional instructions to determine the DBC substrate temperature from output of the temperature sensor.

12. The system of claim 9, further comprising additional instructions to determine the junction temperature based on a coolant temperature and power loss of the power device.

13. The system of claim 12, where the power device is a SiC metal oxide semiconductor field effect transistor (MOSFET).

14. The system of claim 9, where the junction temperature is within the power device.

15. The system of claim 9, further comprising additional instructions to adjust operation of the power device in response to the junction temperature.

16. A method for estimating a junction temperature of a power device, comprising:
generating one or more relationships between a temperature difference between the junction temperature of the power device and the temperature of a substrate;
storing the one or more relationships to memory of a controller;
via the controller, estimating the temperature difference based on the one or more relationships; and
via the controller, estimating the temperature of the power device via adding the temperature of the substrate and the temperature difference between the junction temperature of the power device and the temperature of the substrate.

17. The method of claim 16, further comprising adjusting operation of a second power device in response to the temperature of the power device.

18. The method of claim 17, where the power device is a SiC metal oxide semiconductor field effect transistor (MOSFET).

19. The method of claim 18, where the second power device is a second SiC (MOSFET).

20. The method of claim 16, where the power device is part of a power converter/inverter.
